(19) United States
(12) Patent Application Publication
(10) Pub. No.: US 2026/0206556 A1
(43) Pub. Date: Jul. 16, 2026

(54) GRADIENT ETCHING WITH MICROWAVE OXIDATION

(71) Applicant: Applied Materials, Inc., Santa Clara, CA (US)

(72) Inventors: Mohammad Mahdi TAVAKOLI, Santa Clara, CA (US); Joung Joo LEE, San Jose, CA (US)

(21) Appl. No.: 19/025,199

(22) Filed: Jan. 16, 2025

(51) Int. Cl. H01L 21/768; H01L 21/3213

(52) U.S. Cl. CPC H10W 20/054; H10P 50/266; H10W 20/033; H10W 20/056

(57) ABSTRACT

Embodiments of the present disclosure generally relate to non-plasma methods of processing a substrate. More specifically, the methods disclosed herein incorporate microwave oxidation that is used to selectively etch materials during semiconductor device manufacturing. The method of forming a contact structure on a semiconductor substrate includes performing a microwave oxidation etch process on the contact structure. The microwave oxidation etch process includes flowing a first process gas over the contact structure and delivering a microwave energy to the first process gas without generating a plasma in a processing chamber. The contact structure includes a feature, the feature is defined by a silicon-based portion, a bottom surface, a top-side surface, a first sidewall, and a second sidewall. At least one liner layer is disposed over the contact structure. The method further includes depositing a metal gap fill material over the contact structure to fill the feature.

### BACKGROUND

### Field

Embodiments of the present disclosure generally relate to non-plasma methods of processing a substrate. More specifically, the methods disclosed herein incorporate microwave oxidation that is used to selectively etch materials during semiconductor device manufacturing.

### Description of the Related Art

Integrated circuits have evolved into complex devices that can include millions of transistors, capacitors, and resistors on a single chip. Examples of such a devices include memory (e.g., dynamic random access memory (DRAM)) and logic devices, including both planar and three-dimensional structures. Examples of three-dimensional structures are fin field-effect transistor (finFET) and metal-oxide-semiconductor field-effect transistor (MOSFET) devices. In the course of integrated circuit evolution, functional density (e.g., the number of interconnected devices per chip area) has generally increased while geometry size (e.g., the smallest component (or line) that can be created using a fabrication process) has decreased. Such geometry reduction has driven innovation into various etching processes to assist in the production of patterned devices.

In a traditional middle-of-the-line (MOL) interconnect formation process, a feature, such as a via or trench is fabricated in the semiconductor substrate. MOL contacts allow connections between front-end-of-the-line (FEOL) semiconductor structures and back-end-of-the-line (BEOL) interconnects. Contacts with low resistance are desirable in semiconductor devices. However, when a MOL interconnect has a relatively high resistance, a poor connection is created at the MOL interconnect, which reduces the overall performance of the packaged semiconductor structures.

Conventional MOL and BEOL electrical connections, such as contacts, interconnects, and the like, are formed by filling a feature such as a cavity, trench, or via with a conductive material. Then the feature is filled with a metal material to form a metal fill layer that serves as an interconnect between layers of the device. As devices reach the 1.4 nm node and beyond, molybdenum (Mo) is being used as the material of the metal fill layer or other layer components due to its lower resistivity inside smaller features. However, additional MOL or BEOL processing performed after depositing Mo expose the surface of the Mo metal fill layer to process gases such as nitrogen or ammonia (NH₃), or the gases in the ambient environment, such as O₂ or H₂O, which cause nitridation and oxidation of the surfaces of the formed Mo metal fill layer and significantly increase the resistance of the formed interconnect due to the presence of nitrogen or oxygen containing layers formed on exposed surfaces. In addition, during processing, a liner layer is deposited over the feature, the liner layer may become nitrided during processing. The liner layer causes reduced selectivity during metal fill material deposition. An etch process is needed to remove at least the unwanted portions of the nitridation or oxidation layer and at least a portion of the liner layer.

Dry etch processes are often desirable for selectively removing material from semiconductor substrates, as these processes are capable of gently removing material from miniature structures with minimal physical disturbance. Additionally, dry etch processes have been developed to selectively remove/etch a variety of dielectrics relative to one another. However, such dry etch processes often incorporate the generation of a plasma and/or are conducted at high temperatures in the presence of halogenated process gases. Such process conditions can unintentionally and/or undesirably damage underlying layers of the semiconductor substrate.

Therefore, there is a need to develop new etch processes that can selectively remove materials and minimize the amount of damage to the remaining portions of features that are exposed during the etching process.

### SUMMARY

In a first embodiment, a method of etching a contact structure on a semiconductor substrate is disclosed. The method includes performing a microwave oxidation etch process on the contact structure by flowing a first process gas including oxygen over the contact structure and delivering a microwave energy to the first process gas without generating a plasma in a processing chamber. The contact structure includes a feature formed in a surface of the semiconductor substrate. The feature is defined by a silicon-based portion, a bottom surface, a top-side surface, a first sidewall, and a second sidewall. At least one liner layer is disposed over the feature.

In another embodiment, a method of forming a contact structure on a semiconductor substrate is disclosed. The method includes performing a microwave oxidation etch process on the contact structure. The microwave oxidation etch process includes flowing a first process gas over the contact structure and delivering a microwave energy to the first process gas without generating a plasma in a processing chamber. The contact structure includes a feature formed in a surface of the semiconductor substrate. The feature is defined by a silicon-based portion, a bottom surface, a top-side surface, a first sidewall, and a second sidewall. A first liner layer is disposed over at least a portion of the feature, and a second liner layer is disposed over at least a portion of the first liner layer. The method further includes depositing a metal gap fill material over the contact structure to fill the feature.

In another embodiment, a method of forming a contact structure on a semiconductor substrate is disclosed. The method includes forming a first liner layer over the contact structure by maintaining a first temperature of a substrate and providing a first carrier gas, a first metal-containing precursor, and a first hydrogen-containing precursor to a first processing chamber. The contact structure includes a feature formed in a surface of the semiconductor substrate. The feature is defined by a silicon-based portion, a bottom surface, a top-side surface, a first sidewall, and a second sidewall. The first liner layer is disposed over at least a portion of the feature. The method further includes performing a microwave oxidation etch process on the contact structure, wherein the microwave oxidation etch process includes flowing a first process gas over the contact structure and delivering a microwave energy to the first process gas without generating a plasma in a processing chamber.

### BRIEF DESCRIPTION OF THE DRAWINGS

So that the manner in which the above recited features of the present disclosure can be understood in detail, a more particular description of the disclosure, briefly summarized above, may be had by reference to embodiments, some of which are illustrated in the appended drawings. It is to be noted, however, that the appended drawings illustrate only exemplary embodiments of the disclosure and are therefore not to be considered limiting of its scope, as the disclosure may admit to other equally effective embodiments.

FIG. 1 illustrates a schematic top view of a multi-chamber processing system, according to one or more embodiments.

FIG. 2A is a schematic of a processing chamber that includes a microwave source, according to one or more embodiments.

FIG. 2B is a schematic of a solid state microwave emission module, according to one or more embodiments.

FIG. 2C is a perspective view illustration of a source array for a microwave source, according to one or more embodiments.

FIG. 2D is a cross-sectional illustration of a processing chamber for processing a substrate, according to one or more embodiments.

FIG. 3 is a flow diagram that depicts a method of processing a substrate, according to one or more embodiments.

FIGS. 4A, 4B, 4C, and 4D illustrate views of various stages of forming a contact structure on a substrate, according to one or more embodiments.

To facilitate understanding, identical reference numerals have been used, where possible, to designate identical elements that are common to the figures. It is contemplated that elements and features of one embodiment may be beneficially incorporated in other embodiments without further recitation.

### DETAILED DESCRIPTION

Embodiments of the present disclosure generally relate to non-plasma methods of processing a substrate. More specifically, the methods disclosed herein incorporate microwave oxidation that is used to selectively etch materials during semiconductor device manufacturing. Middle-of-the-line (MOL) and back-end-of-the-line (BEOL) electrical connections, such as interconnects, and the like are formed by filling a feature such as a cavity, trench, or via with a conductive material that is in contact with an underlying metal layer, the conductive material is a metal fill material. During processing, a metal gap fill layer is deposited into the feature by a bottom-up growth method. Conventional bottom-up growth methods are challenging due to selectivity loss and seam formation if a metal liner is deposited along the sidewalls, top-side, and bottom of the feature. Further, conventional methods to remove a metal liner from the sidewalls and the top-side surface of the feature require multiple cycles of etch processing, multiple chambers, and cause damage to the dielectric material of the feature. As disclosed within, a gradient etching process, which utilizes microwave enhanced non-plasma processing methods, is used to selectively etch a liner layer (e.g., a titanium nitride (TiN) layer and/or a titanium silicide (TiSi) layer) from the sidewalls and top-side of the feature. The microwave oxidation etch process promotes a seam free metal gap fill process, which ultimately forms an interconnect with lower resistivity.

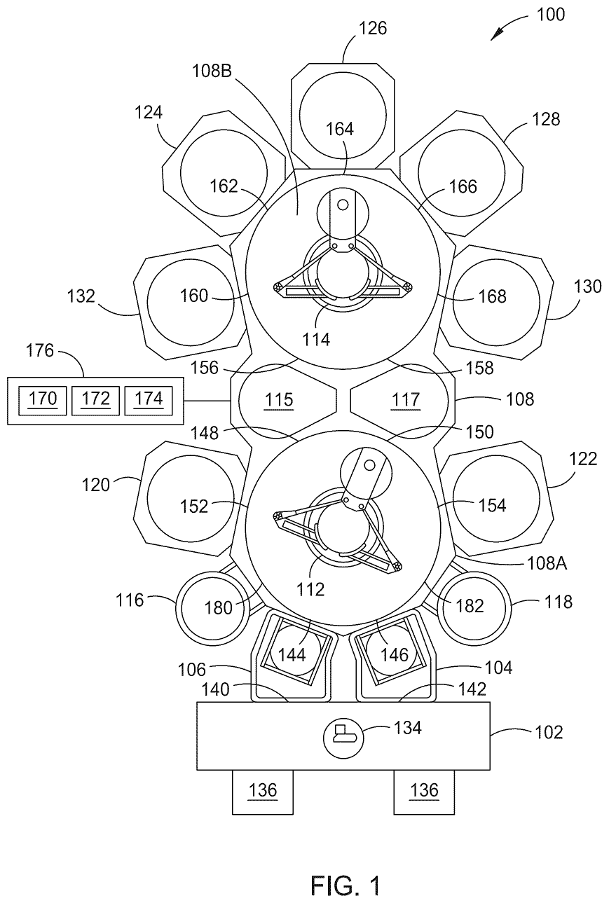

FIG. 1 illustrates a schematic top view of a multi-chamber processing system 100 according to one or more embodiments. The multi-chamber processing system 100 can be used for creating a bottom lateral recess (an etch recess) in a device substrate to anchor a metal material of an MOL or BEOL electrical connection during a chemical mechanical polishing (CMP) process. As detailed below, substrates in the processing system 100 may be processed in and transferred between the various chambers without exposing the substrates to an ambient environment exterior to the processing system 100 (for example, an atmospheric ambient environment may be present in a fab). For example, the substrates may be processed in and transferred between the various chambers maintained at a low pressure (for example, less than or equal to about 300 Torr) or sub-atmospheric pressure, such as a vacuum environment, without breaking the reduced relative pressure or vacuum environment among various processes performed on the substrates in the processing system 100. Accordingly, the processing system 100 may provide for an integrated solution for some processing of substrates.

The multi-chamber processing system 100 generally includes a factory interface 102, load lock chambers 104, 106, a transfer chamber 108 (with a first portion 108A and a second portion 108B) with respective transfer robots 112, 114, holding chambers 115, 117, one or more optional service chambers 116, 118, and processing chambers 120, 122, 124, 126, 128, 130, 132. In one or more embodiments, the first portion 108A of the transfer chamber 108 and the second portion 108B of the transfer chamber 108 are separate transfer chambers. As detailed herein, substrates in the multi-chamber processing system 100 can be processed in and transferred between the various chambers without exposing the substrates to an ambient environment exterior to the multi-chamber processing system 100, for example, an atmospheric ambient environment such as may be present in a fab. The substrates can be processed in and transferred between the various chambers maintained at a low pressure, for example, less than or equal to about 300 Torr, or a vacuum environment without breaking the low pressure or vacuum environment among various processes performed on the substrates in the multi-chamber processing system 100. Accordingly, the multi-chamber processing system 100 may provide for an integrated solution for processing of substrates.

Examples of multi-chamber processing systems that may be suitably modified in accordance with the teachings provided herein include the Endura®, Producer®, or Centura® integrated multi-chamber processing systems or other suitable multi-chamber processing systems commercially available from Applied Materials, Inc., located in Santa Clara, California. It is contemplated that other multi-chamber processing systems (including those from other manufacturers) may be adapted to benefit from aspects described herein.

In the illustrated example of FIG. 1, the factory interface 102 includes a docking station and at least one factory interface robot 134 to facilitate transfer of substrates. The docking station is adapted to accept one or more front opening unified pods (FOUPs) 136. In some examples, each factory interface robot 134 generally includes a blade disposed on one end of the respective factory interface robot 134 adapted to transfer the substrates from the factory interface 102 to the load lock chambers 104, 106.

The load lock chambers 104, 106 have respective ports 140, 142 coupled to the factory interface 102 and respective ports 144, 146 coupled to the transfer chamber 108. The first portion 108A of the transfer chamber 108 further has respective ports 148, 150 coupled to the holding chambers 115, 117, respective ports 180,182 coupled to one or more optional service chambers 116, 118, and respective ports 152, 154 coupled to processing chambers 120, 122. Similarly, the second portion 108B of the transfer chamber 108 has respective ports 156, 158 coupled to the holding chambers 115, 117 and respective ports 160, 162, 164, 166 coupled to processing chambers 124, 126, 128, 130, 132. The ports 144, 146, 148, 150, 152, 154, 156, 158, 160, 162, 164, 166, 180, 182 can be, for example, slit valve openings with slit valves for passing substrates therethrough by the transfer robots 112, 114 and for providing a seal between respective chambers to prevent a gas from passing between the respective chambers. Generally, any port is open for transferring a substrate therethrough. Otherwise, the port is closed.

The load lock chambers 104, 106, the transfer chamber 108, the holding chambers 115, 117, one or more optional service chambers 116, 118, and the processing chambers 120, 122, 124, 126, 128, 130, 132 may be fluidly coupled to a gas and pressure control system (not specifically illustrated). The gas and pressure control system can include one or more gas pumps (for example, turbo pumps, cryo-pumps, roughing pumps) gas sources, various valves, and conduits fluidly coupled to the various chambers. In operation, the factory interface robot 134 transfers a substrate from the FOUP 136 through the port 140 or 142 to the load lock chamber 104 or 106. The gas and pressure control system then pumps down the load lock chamber 104 or 106. The gas and pressure control system further maintains the transfer chamber 108 and the holding chambers 115, 117 with an interior low pressure or vacuum environment (which may include an inert gas). Hence, the pumping down of the load lock chamber 104 or 106 facilitates passing the substrate between, for example, the atmospheric environment of the factory interface 102 and the low pressure or vacuum environment of the transfer chamber 108. In some embodiments, one or more optional service chambers (shown as 116 and 118) may be coupled to the transfer chamber 108. The service chambers 116 and 118 may be configured to perform other substrate processes, such as degassing, orientation, substrate metrology, cool down, and the like.

With the substrate in the load lock chamber 104 or 106 that has been pumped down, the transfer robot 112 transfers the substrate from the load lock chamber 104 or 106 into the transfer chamber 108 through the port 144 or 146. The transfer robot 112 is then capable of transferring the substrate to and/or between any of the processing chambers 120, 122 through the respective ports 152, 154 for processing, the one or more optional service chambers 116, 118 through the respective ports 180, 182, and the holding chambers 115, 117 through the respective ports 148, 150 for holding to await further transfer. Similarly, the transfer robot 114 is capable of accessing the substrate in the holding chamber 115 or 117 through the port 156 or 158 and is capable of transferring the substrate to and/or between any of the processing chambers 124, 126, 128, 130, 132 through the respective ports 160, 162, 164, 166, 168 for processing and the holding chambers 115, 117 through the respective ports 156, 158 for holding to await further transfer. The transfer and holding of the substrate within and among the various chambers can be in the low pressure or vacuum environment provided by the gas and pressure control system.

The processing chambers 120, 122, 124, 126, 128, 130, 132 can be any appropriate chamber for processing a substrate. In some examples, the processing chamber 120 can be capable of performing an etch process, the processing chamber 122 can be capable of performing a cleaning process, and the processing chambers 126, 128, 130, 132 can be capable of performing respective growth processes. The processing chamber 120 may be a Selectra™ Etch chamber available from Applied Materials of Santa Clara, Calif. The processing chamber 122 may be a SiCoNi™ Preclean chamber available from Applied Materials of Santa Clara, Calif. The processing chamber 124, 126, 128, 130, or 132 may be a Volta™ CVD/ALD chamber, Trillium™ ALD chamber, or Encore™ PVD chambers available from Applied Materials of Santa Clara, Calif.

A system controller 176 is coupled to the multi-chamber processing system 100 for controlling the multi-chamber processing system 100 or components thereof. For example, the system controller 176 may control the operation of the multi-chamber processing system 100 using a direct control of the chambers 104, 106, 108, 115, 116, 117, 118, 120, 122, 124, 126, 128, 130, 132 of the multi-chamber processing system 100 or by controlling controllers associated with the chambers 104, 106, 108, 115, 116, 117, 118, 120, 122, 124, 126, 128, 130, 132. In operation, the system controller 176 enables data collection and feedback from the respective chambers to coordinate performance of the multi-chamber processing system 100.

The system controller 176 generally includes a central processing unit (CPU) 170, memory 172, and support circuits 174. The CPU 170 may be one of any form of a general-purpose processor that can be used in an industrial setting. The memory 172, non-transitory computer-readable medium, or machine-readable storage device, is accessible by the CPU 170 and may be one or more of memory such as random access memory (RAM), read only memory (ROM), floppy disk, hard disk, or any other form of digital storage, local or remote. The support circuits 174 are coupled to the CPU 170 and may comprise cache, clock circuits, input/output subsystems, power supplies, and the like. The various methods disclosed herein may generally be implemented under the control of the CPU 170 by the CPU 170 executing computer instruction code stored in the memory 172 (or in memory of a particular processing chamber) as, for example, a software routine. That is, the computer program product is tangibly embodied on the memory 172 (or non-transitory computer-readable medium or machine-readable storage device). When the computer instruction code is executed by the CPU 170, the CPU 170 controls the chambers to perform processes in accordance with the various methods.

The instructions in memory 172 may be in the form of a program product, such as a program that implements the methods of the present disclosure. In one example, the disclosure may be implemented as a program product stored on a computer-readable storage media for use with a computer system. The program(s) of the program product define functions of the implementations (including the methods described herein). Thus, the computer-readable storage media, when carrying computer-readable instructions that direct the functions of the methods described herein, are implementations of the present disclosure. The system controller 176 is configured to perform methods such as the method 300 stored in the memory 172.

As will be described further below, in one or more embodiments of the substrate processing sequence described herein, all of the processes are performed under vacuum within the processing system 100. In one example of the processing system 100, a remote-plasma-source (RPS) cleaning process is performed in chamber 122, a precleaning process is performed in chamber 120, and one or more of a deposition, an etching, and/or a thermal processing process is performed in at least one of the chambers 132, 124, 126, 128, and 130. In one example, the remote plasma (RPS) assisted process performed in chamber 122 is performed in a processing chamber, such as Aktiv™ Preclean (APC) chamber available from Applied Materials of Santa Clara, Calif. In another example, the processing chambers 132, 124, 126, 128, or 130 may be a Volta™ CVD/ALD chamber, or Encore™ PVD chambers available from Applied Materials of Santa Clara, Calif.

In another example of the processing system 100, a remote-plasma-source (RPS) cleaning process and a precleaning process are both performed in at least one of the chambers 122 and 120, and one or more of a deposition, an etching, and/or a thermal processing process is performed in at least one of the chambers 132, 124, 126, 128, and 130. In one example, the processing chambers 132, 124, 126, 128, or 130 may be a Volta™ CVD/ALD chamber, or Encore™ PVD chambers available from Applied Materials of Santa Clara, Calif.

Other processing systems can be in other configurations. For example, more or fewer processing chambers may be coupled to a transfer apparatus. In the illustrated example, the transfer apparatus includes the transfer chambers 108 and the holding chambers 115, 117. In other examples, more or fewer transfer chambers (e.g., one transfer chamber) and/or more or fewer holding chambers (e.g., no holding chambers) may be implemented as a transfer apparatus in a processing system.

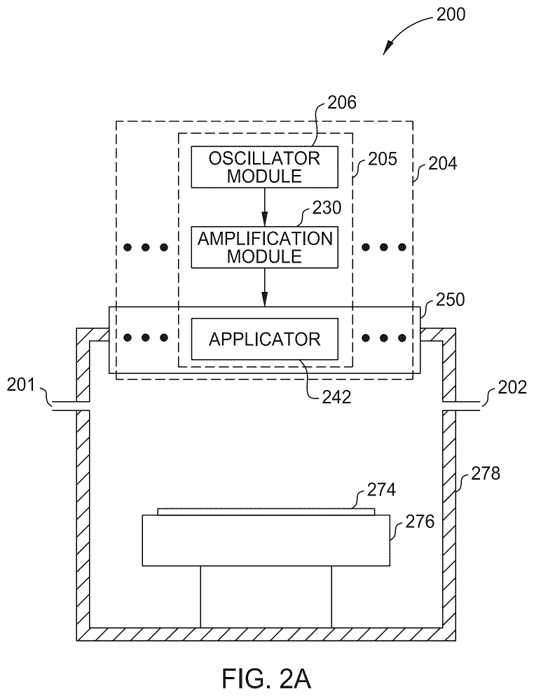

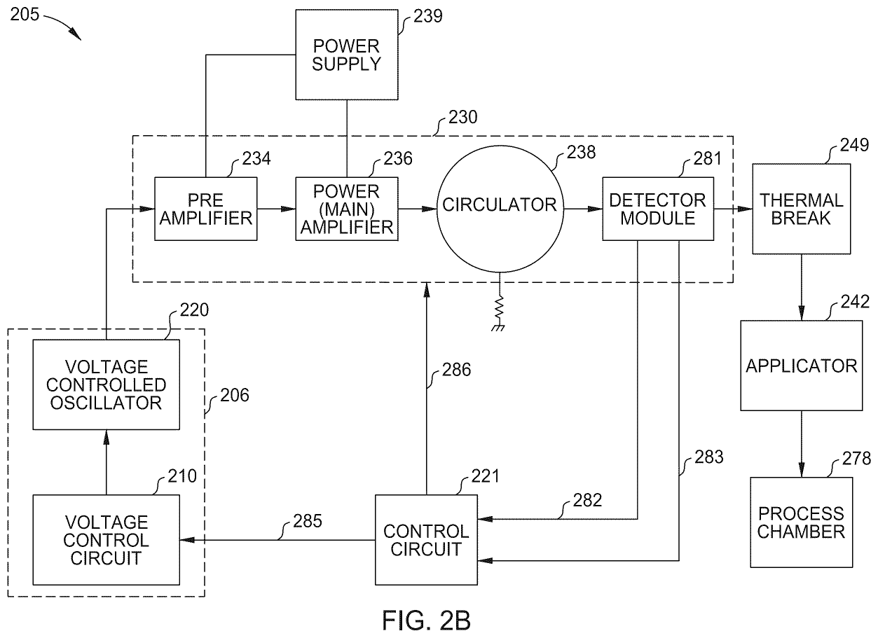

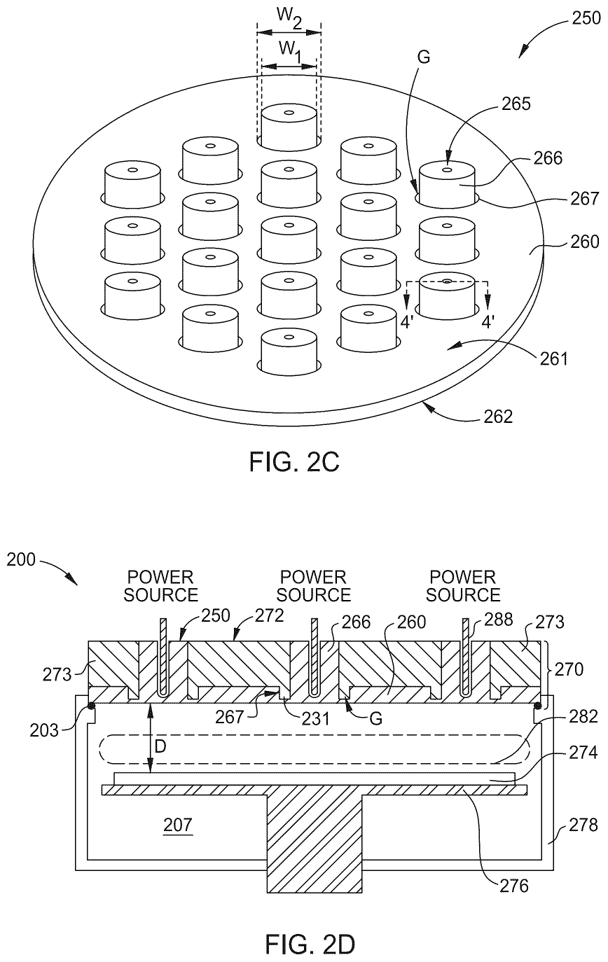

FIGS. 2A and 2B depict an example of a processing tool 200. The processing tool 200 is configured to deliver microwave energy to a processing region of the process chamber to perform a selective etching process on a substrate, which can be performed at a desired processing temperature.

FIG. 2A is a cross-sectional illustration of a microwave processing tool 200 (referred to as processing tool 200 for short). In some embodiments, the processing tool 200 may be a processing tool suitable for any type of processing operation that requires the delivery of microwave energy. In some embodiments, one or more of the chambers 120 and 122, or even chambers 132-140, may include the processing tool 200. The processing tool may emit high-frequency electromagnetic radiation in the form of microwave energy. In some embodiments, “High-frequency” may refer to frequencies between 300 MHz and 1000 GHz. In some embodiments, the high-frequency electromagnetic radiation is provided at frequencies in the “S-band”, such as frequencies between about 2.4 GHz and about 2.6 GHz.

Generally, embodiments include a processing tool 200 that includes a chamber 278. In processing tool 200, the chamber 278 may be a vacuum chamber. A vacuum chamber may include a pump (not shown) for removing gases from the chamber to provide the desired vacuum. Additional embodiments may include a chamber 278 that includes one or more gas lines 201 for providing processing gases into the chamber 278 and exhaust lines 202 for removing byproducts from the chamber 278. While not shown, it is to be appreciated that gas may also be injected into the chamber 278 through a source array 250 (e.g., as a showerhead) for evenly distributing the processing gases over a substrate 274.

In an embodiment, the substrate 274 may be supported on a chuck 276. For example, the chuck 276 may be any suitable chuck, such as an electrostatic chuck. The chuck 276 may also include cooling lines and/or a heater to provide temperature control to the substrate 274 during processing. Due to the modular configuration of the high-frequency emission modules described herein, embodiments allow for the processing tool 200 to accommodate any sized substrate 274. For example, the substrate 274 may be a semiconductor wafer (e.g., 200 mm, 300 mm, 450 mm, or larger). Alternative embodiments also include substrates 274 other than semiconductor wafers. For example, embodiments may include a processing tool 200 configured for processing glass substrates, (e.g., for display technologies).

According to an embodiment, the processing tool 200 includes a modular high-frequency emission source 204. The modular high-frequency emission source 204 may comprise an array of solid state high-frequency emission modules 205. In an embodiment, each solid state high-frequency emission module 205 may include an oscillator module 206, an amplification module 230, and an applicator 242. As shown, the applicators 242 are schematically shown as being integrated into the source array 250.

In an embodiment, the oscillator module 206 and the amplification module 230 may comprise electrical components that are solid state electrical components. In an embodiment, each of the plurality of oscillator modules 206 may be communicatively coupled to different amplification modules 230. For example, each oscillator module 206 may be electrically coupled to a single amplification module 230. In an embodiment, the plurality of oscillator modules 206 may generate incoherent electromagnetic radiation. Accordingly, the electromagnetic radiation induced in the chamber 278 will not interact in a manner that results in an undesirable interference pattern.

In an embodiment, each oscillator module 206 generates high frequency electromagnetic radiation that is transmitted to the amplification module 230. After processing by the amplification module 230, the electromagnetic radiation is transmitted to the applicator 242. In an embodiment, the applicators 242 each emit electromagnetic radiation into the chamber 278. In some embodiments, the applicators 242 couple the electromagnetic radiation to the processing gases in the chamber 278 to provide energy thereto, without forming a plasma.

FIG. 2B is a schematic of a solid state high-frequency emission module 205. In an embodiment, the solid state high-frequency emission module 205 comprises an oscillator module 206. The oscillator module 206 may include a voltage control circuit 210 for providing an input voltage to a voltage controlled oscillator 220 in order to produce high-frequency electromagnetic radiation at a desired frequency. The voltage controlled oscillator 220 is an electronic oscillator whose oscillation frequency is controlled by the input voltage. According to an embodiment, the input voltage from the voltage control circuit 210 results in the voltage controlled oscillator 220 oscillating at a desired frequency.

According to an embodiment, the electromagnetic radiation is transmitted from the voltage controlled oscillator 220 to an amplification module 230. The amplification module 230 may include a driver/pre-amplifier 234, and a main power amplifier 236 that are each coupled to a power supply 239. According to an embodiment, the amplification module 230 may operate in a pulse mode. For example, the amplification module 230 may have a duty cycle between 1% and 99%. In a more particular embodiment, the amplification module 230 may have a duty cycle between approximately 15% and 50%.

In an embodiment, the electromagnetic radiation may be transmitted to the thermal break 249 and the applicator 242 after being processed by the amplification module 230. However, part of the power transmitted to the thermal break 249 may be reflected back due to the mismatch in the output impedance. Accordingly, some embodiments include a detector module 281 that allows for the level of forward power 283 and reflected power 282 to be sensed and fed back to the control circuit module 221. It is to be appreciated that the detector module 281 may be located at one or more different locations in the system (e.g., between the circulator 238 and the thermal break 249). In an embodiment, the control circuit module 221 interprets the forward power 283 and the reflected power 282, and determines the level for the control signal 285 that is communicatively coupled to the oscillator module 206 and the level for the control signal 286 that is communicatively coupled to the amplification module 230. In an embodiment, control signal 285 adjusts the oscillator module 206 to optimize the high-frequency radiation coupled to the amplification module 230. In an embodiment, control signal 286 adjusts the amplification module 230 to optimize the output power coupled to the applicator 242 through the thermal break 249. In an embodiment, the feedback control of the oscillator module 206 and the amplification module 230, in addition to the tailoring of the impedance matching in the thermal break 249, may allow for the level of the reflected power to be less than approximately 5% of the forward power. In some embodiments, the feedback control of the oscillator module 206 and the amplification module 230 may allow for the level of the reflected power to be less than approximately 2% of the forward power.

Accordingly, embodiments allow for an increased percentage of the forward power to be coupled into the chamber 278, and increases the available power provided to the process gases disposed within the processing volume. Furthermore, impedance tuning using a feedback control is superior to impedance tuning in typical slot-plate antennas. In slot-plate antennas, the impedance tuning involves moving two dielectric slugs formed in the applicator. This involves mechanical motion of two separate components in the applicator, which increases the complexity of the applicator.

Referring now to FIG. 2C, a perspective view illustration of a source array 250 is shown, in accordance with an embodiment. In an embodiment, the source array 250 comprises a dielectric plate 260. A plurality of cavities 267 are disposed into a first surface 261 of the dielectric plate 260. The cavities 267 do not pass through to a second surface 262 of the dielectric plate 260. The source array 250 may further include a plurality of dielectric resonators 266. Each of the dielectric resonators 266 may be in a different one of the cavities 267. Each of the dielectric resonators 266 may comprise a hole 265 in the axial center of the dielectric resonator 266.

In an embodiment, the dielectric resonators 266 may have a first width W1, and the cavities 267 may have a second width W2. The first width W1 of the dielectric resonator 266 is smaller than the second width W2 of the cavities 267. The difference in the widths provides a gap G between a sidewall of the dielectric resonators 266 and a sidewall of the cavity 267. In the illustrated embodiment, each of the dielectric resonators 266 are shown as having a uniform width W1. However, it is to be appreciated that not all dielectric resonators 266 of a source array 250 need to have the same dimensions.

Referring now to FIG. 2D, a cross-sectional illustration of a processing tool 200 that includes an assembly 270 is shown, in accordance with an embodiment. In an embodiment, the processing tool comprises a chamber 278 that is sealed by an assembly 270. For example, the assembly 270 may rest against one or more O-rings 203 to provide a vacuum seal to an interior chamber volume 207 of the chamber 278. In other embodiments, the assembly 270 may interface with the chamber 278. That is, the assembly 270 may be part of a lid that seals the chamber 278. In an embodiment, the processing tool 200 may comprise a plurality of processing volumes (which may be fluidically coupled together), with each processing volume having a different assembly 270. In an embodiment, a chuck 276 or the like may support a substrate 274. The substrate 274 may be a distance D from the assembly 270. In an embodiment, the interior chamber volume 207 may be suitable for delivering microwave energy to a process gas disposed within the chamber 278. That is, the chamber 278 may be a vacuum chamber.

In an embodiment, the assembly 270 comprises a source array 250 and a housing 272. The source array 250 may comprise a dielectric plate 260 and a plurality of dielectric resonators 266 extending up from the dielectric plate 260. Cavities 267 into the dielectric plate 260 may surround each of the dielectric resonators 266. Sidewalls of the cavity 267 are separated from the sidewall of the dielectric resonator 266 by a gap G. The dielectric plate 260 and the dielectric resonators 266 of the source array 250 may be a monolithic structure (as shown in FIG. 2D), or the dielectric plate 260 and the dielectric resonators 266 may be discrete components.

The housing 272 includes rings 231 that fit into the gaps G. In an embodiment, the rings 231 and the conductive body 273 of the housing 272 are a monolithic structure (as shown in FIG. 2D), or the conductive body 273 and the rings 231 may be discrete components. The housing 272 may having openings sized to receive the dielectric resonators 266. In an embodiment, monopole antennas 288 may extend into holes in the dielectric resonators 266. The monopole antennas 288 are each electrically coupled to power sources (e.g., solid state high-frequency emission modules 205).

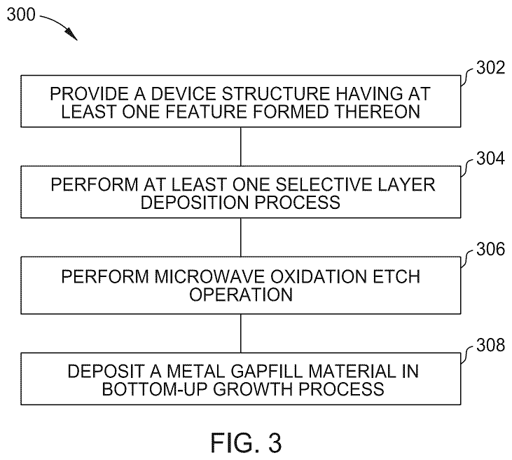

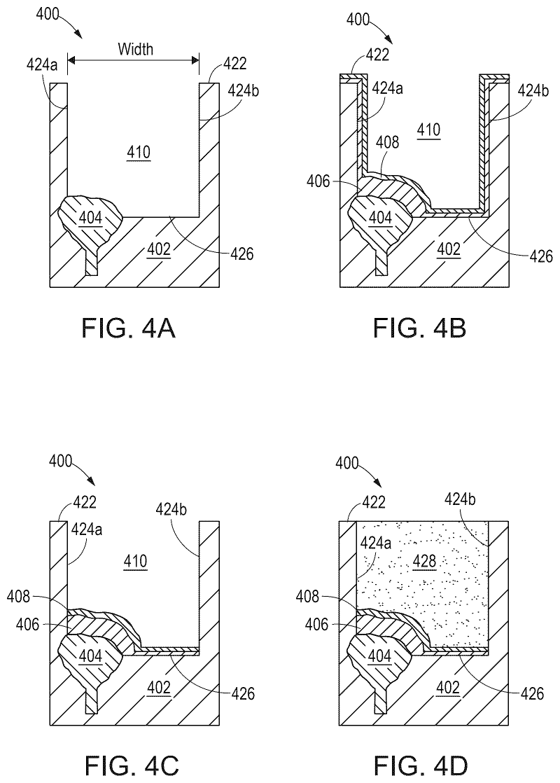

FIG. 3 is a flow diagram depicting a method of processing a substrate to form, for example, middle-of-line (MOL) and back-end-of-line (BEOL) structures. FIGS. 4A, 4B, 4C, and 4D are cross-sectional views of various stages of forming a contact structure 400 on a substrate 402. The substrate 402 is a semiconductor substrate. FIGS. 4A-4D are only partial schematic views of the contact structure 400, and the contact structure 400 may contain any number of transistor sections and additional materials having aspects as illustrated in the figures. It should also be noted that although the method illustrated in FIG. 3 is described sequentially, other process sequences that include one or more operations that have been omitted and/or added, and/or has been rearranged in another desirable order, fall within the scope of the embodiments of the disclosure provided herein. Method 300 may be performed in a processing chamber (e.g., processing chambers 120, 122, 124, 126, 128, 130, or 132), as shown in FIG. 1.

As shown in FIG. 4A, at operation 302, the contact structure 400 includes at least one feature formed in a surface of the substrate 402. The contact structure 400 has a silicon-based portion 404 that is exposed in a cavity 410 of the substrate 402 formed of a dielectric material. The substrate 402 includes silicon (Si) or germanium (Ge); a compound including, for example, silicon dioxide, silicon nitride, silicon carbide, gallium arsenide, gallium phosphide, indium phosphide, indium arsenide, and/or indium antimonide; an alloy including, for example, SiGe, GaAsP, AlInAs, GaInAs, GaInP, and/or GaInAsP; a combination thereof, or the like. In some embodiments, the silicon-based portion 404 may be a silicon material or a silicon germanium (SiGe) material.

In one or more embodiments, the feature is a cavity 410, a via, or a trench. A cavity 410 is shown in FIG. 4A. The cavity 410 can includes an average width. For example, cavity 410 can have a width (shown in FIG. 3A) of about 35 nanometers (nm) or less, such as about 5 nm to about 35 nm, such as about 5 nm, 10 nm, and 15 nm to about 20 nm, 25 nm, 30 nm, or 35 nm. In one or more embodiments, cavity 410 can have an aspect ratio (depth:width) of about 1:1 to about 100:1, such as about 10:1, 15:1, or 25:1 to about 35:1, 45:1, or 50:1. The contact structure 400 includes at least a first sidewall 424a, a second sidewall 424b, a bottom surface 426, and a top-side surface 422.

As shown in FIG. 4B, at operation 304, at least one selective layer deposition processes is performed to produce at least one selective layer. The selective layer may be a liner layer or a capping layer. For example, a first layer 406 is deposited over the feature such that it contacts the first sidewall 424a, the second sidewall 424b, the bottom surface 426, and the top-side surface 422 of the cavity 410. The first layer 406 is a titanium containing layer such as a Ti layer, and/or a TiSi layer. TiSi is TixSiy which may include Ti₅Si₃, TiSi₂, TiSi, or combinations thereof. The process is selective to the silicon-based portion 404 over the dielectric material of the substrate 402, but a thin titanium containing layer may also form on the surfaces of the top-side surface 422 of the substrate 402 and on the first sidewall 424a and the second sidewall 424b in the cavity 410, including a bottom surface 426 of the cavity 410. In some embodiments, the selective deposition process is a chemical vapor deposition (CVD) TiSi process, such as a plasma enhanced CVD process (PECVD), with selectivity on silicon (Si) or silicon germanium (SiGe) over oxide/SiN of approximately greater than 30:1 (vol/vol). Selective TiSi deposition can be performed using any suitable CVD or ALD process. In some embodiments, the CVD or ALD process includes utilizing a plasma with a carrier gas. The plasma/carrier gas may then be introduced towards the surface of the semiconductor substrate. In one or more embodiments, the carrier gas includes a noble gas, such as argon, neon, helium, or combinations thereof. The selective deposition process can provide a thickness of TiSi of approximately 3 nm to approximately 9 nm on the silicon-based portion 404, in which a selectivity loss on the top-side surface 422, the first sidewall 424a, the second sidewall 424b and the bottom surface 426 of the cavity 410 is generally less than approximately 1 angstrom to approximately 30 angstroms.

In one or more embodiments, selective deposition is performed by introducing a hydrogen-containing precursor by utilizing a conductively coupled plasma (CCP) deposition. In one or more embodiments, selective deposition includes introducing a hydrogen-containing precursor and a metal-containing precursor with the carrier gas. In one or more embodiments, the metal-containing precursor gas may be fluorine free to prevent formation of metal fluoride solids that have undesirable resistivity properties. The hydrogen-containing precursor can include molecular hydrogen (H₂) and the metal-containing precursor is titanium chloride (TiCl₄). Without being bound by theory, the introduction of both the hydrogen-containing and the metal-containing precursors into the carrier gas causes both precursors to become energized on a molecular level to a point of at least partial disassociation in the carrier gas. For example, titanium chloride may disassociate into titanium-based ions (Ti⁺, TiClₓ ⁺) or free radial titanium trichloride (TiCl₃^{*}); hydrogen may disassociate into hydronium ions (H⁺) or hydrogen free radicals (H*). The dissociated species may then interact with the silicon surface of the silicon-containing contact, donate electrons to the silicon atoms and then each species interact with one another and form the titanium silicide layer on the top of the silicon-based portion 404.

In one or more embodiments, the selective deposition is performed by maintaining the semiconductor substrate at a first metal deposition temperature. In one or more embodiments, the semiconductor substrate is maintained at a metal deposition temperature of about 200° C. to 800° C., such as about 200° C., 300° C., 400° C., 450° C., and 500° C. to about 600° C., 700° C., and 800° C., for a period of about 100 seconds to about 1000 seconds, in which an inert gas may be present. The inert gas flowing over the semiconductor substrate may facilitate in cooling and affixing the deposition material (e.g., TiSi) on the top of the silicon-containing contact as well as removing volatilized products and unreacted materials, such as molecular hydrogen and hydrogen chloride (HCl).

In one or more embodiments, as shown in FIG. 4B, a second deposition process is performed to deposit or produce a second layer 408 over first layer 406. The second layer 408 may be a second liner layer or a capping layer. The second layer 408 is deposited over the cavity 410. In one or more embodiments, the second layer 408 is a conformal layer. The second layer 408 is a nitrogen containing layer. For example, the nitrogen containing layer can include a TiN layer and/or a TiSiN layer. In one or more embodiments, the process is selective to the first layer 406 over the dielectric material of the substrate 402 such that the second layer 408 is conformal over the first layer 406. The second layer 408 may also form on the top-side surface 422 of the substrate 402 and on the first sidewall 424a and the second sidewall 424b in the cavity 410, including a bottom surface 426 of the cavity 410. In some embodiments, the selective deposition process is a CVD TiN process, e.g., a plasma enhanced CVD process (PECVD). The selective deposition process can provide a thickness of TiN of approximately 3 nm to approximately 9 nm on the silicon-based portion 404, in which a selectivity loss on the top-side surface 422, the first sidewall 424a, the second sidewall 424b, and the bottom surface 426 of the cavity 410 is generally less than approximately 10 angstrom to approximately 30 angstroms. In one or more embodiments, the first selective capping layer is non-selective. The non-selective deposition process is an ALD TiN process.

Selective deposition of the second layer 408 can be performed using any suitable CVD, PE-CVD, or ALD process. In some embodiments, the CVD, PE-CVD, or ALD process includes utilizing a plasma with a carrier gas. The plasma/carrier gas may then be introduced towards the surface of the semiconductor substrate. In one or more embodiments, the carrier gas includes a noble gas, such as argon, neon, helium, or combinations thereof.

In one or more embodiments, selective deposition is performed by introducing a hydrogen-containing precursor by utilizing a conductively coupled plasma (CCP) deposition. In one or more embodiments, selective deposition includes introducing a hydrogen-containing precursor, a nitrogen containing precursor, and a metal-containing precursor with the carrier gas. In one or more embodiments, the metal-containing precursor gas may be fluorine free to prevent formation of metal fluoride solids that have undesirable resistivity properties. The hydrogen-containing precursor can include molecular hydrogen (H₂), the nitrogen containing precursor is nitrogen (N₂), or ammonia (NH₄) and the metal-containing precursor is titanium chloride (TiCl₄). Without being bound by theory, the introduction of the hydrogen-containing, the nitrogen-containing, and the metal-containing precursors into the carrier gas causes both precursors to become energized on a molecular level to a point of at least partial disassociation in the carrier gas.

In one or more embodiments, the selective deposition is performed by maintaining the semiconductor substrate at a first metal deposition temperature. In one or more embodiments, the semiconductor substrate is maintained at a metal deposition temperature of about 200° C. to 800° C., such as about 200° C., 300° C., 400° C., 450° C., and 500° C. to about 600° C., 700° C., and 800° C., for a period of about 5 seconds to about 20 seconds, in which an inert gas may be present. The inert gas flowing over the semiconductor substrate may facilitate in cooling and affixing the deposition material (e.g., TiN) on the top of the first capping layer as well as removing volatilized products and unreacted materials, such as molecular hydrogen and hydrogen chloride (HCl).

Additionally or alternatively, at operation 304, the second layer 408 is formed by a chemical modification process. For example, a chemical modification process is performed on the first layer 406 to produce a nitrided layer (a nitrogen containing layer), such as a TiSiN layer over the first layer 406, as shown in FIG. 4B. The chemical modification process can include a nitridation process via flowing a nitrogen based gas (N₂), hydrogen (H₂), a nitrogen radical such as an ammonia radical, and/or a nitrogen based compound such as ammonia over the first layer 406 to convert the first layer 406 into a nitrided layer (e.g., the second layer 408). The chemical modification process can include flowing 500 sccm to about 6000 sccm of nitrogen gas (e.g., ammonia) over the first layer 406.

At operation 306, as shown in FIG. 4C, a microwave oxidation etch process is performed on the contact structure 400. The microwave oxidation etch process includes flowing a process gas into the process chamber and delivering a microwave energy to the flowing process gas to perform an etch operation on the substrate 402. In one example, the process gas is oxygen (O₂). The microwave oxidation etch process of operation 306 is selective because the process gas is consumed by the etching process allowing for portions of the first layer 406 and/or second layer 408 to be etched away. The process gas used during the microwave oxidation etch process does not etch other components of the contact structure 400 (e.g., the microwave oxidation etch process is operated in a “starvation mode” such that the process gas is consumed before it etches additional layers or materials of the contact structure 400). In one or more embodiments, the microwave oxidation etch process is a gradient etch process. As shown in FIG. 4C, the first layer 406 and the second layer 408 are etched away from the top-side surface 422 and at least a portion of the first sidewall 424a and the second sidewall 424b. The microwave oxidation etch process continues until the first layer 406 and the second layer 408 are etched away to a desired amount. For example, the duration (in seconds) of the microwave oxidation etch process is controlled until the first liner layer and/or the second liner layer is etched away from the top-side surface 422, the first sidewall 424a and the second sidewall 424b. The microwave oxidation etch process is stopped such that the first layer 406 and/or the second liner layer 408 remains along the silicon contact 404 and the bottom surface 426 of the contact structure 400. As shown in FIG. 4C, the first layer 406 and the second layer 408 remain along at least the bottom surface 426 of the cavity 410 and the silicon-based portion 404.

In some embodiments, operation 306 may include pulsing the delivery of the microwave energy in a sequence that has a duty cycle of between 1% and 99%, such as between 20% and 80%. The pulsing process is performed while the process gas is flowing and until the selective etching process removes a desired amount of material from the substrate. The processes performed during operation 306 include the delivery of the microwave energy at a power level that does not generate a plasma in the processing region over the surface of the substrate, which can be verified by use of various metrology techniques that can include the use of a Langmuir probe or optical detection technique.

The process gas may include one or more oxygen based process gases, such as O₂ gas, ozone, and combinations thereof. In at least one embodiment, the process gas is O₂ gas. The process gas may be flowed into the processing chamber at a flow rate of about 1 sccm to about 100 sccm, such as about 2.5 sccm to about 50 sccm, such as about 5 sccm to about 25 sccm, alternatively about 1 sccm to about 2.5 sccm, alternatively about 2.5 sccm to about 5 sccm, alternatively about 5 sccm to about 10 sccm, alternatively about 10 sccm to about 25 sccm, alternatively about 25 sccm to about 50 sccm, alternatively about 50 sccm to about 100 sccm. The oxygen based process gas may be flowed into the processing chamber for about 1 min to about 10 min, such as about 2 min to about 8 min, such as about 4 min to about 6 min, alternatively about 1 min to about 2 min, alternatively about 2 min to about 4 min, alternatively about 4 min to about 5 min, alternatively about 5 min to about 6 min, alternatively about 6 min to about 8 min, alternatively about 8 min to about 10 min, alternatively about 2 min to about 5 min.

The etch operation of operation 306 may be conducted without generating a plasma. In some embodiments, the lack of generated electromagnetic radiation at frequencies not provided to the processing region of the process chamber, such as wavelengths in the visible region, can be used to detect that a plasma has not been formed within the processing region. In at least one embodiment, the temperature within the processing chamber during operation 306 may be maintained at about 0° C. to about 500° C., such as about 10° C. to about 400° C., such as about 20° C. to about 350° C., alternatively about 100° C. to about 200° C., alternatively about 200° C. to about 250° C., alternatively about 250° C. to about 300° C., alternatively about 300° C. to about 350° C., alternatively about 350° C. to about 400° C., alternatively about 400° C. to about 500° C. In at least one embodiment, the pressure within the processing chamber during operation 306 is about 1 mTorr to about 100 Torr, such as about 10 mTorr to about 1 Torr, such as about 20 mTorr to about 100 mTorr, such as about 40 mTorr to about 80 mTorr, alternatively about 40 mTorr to about 60 mTorr, alternatively about 20 mTorr to about 40 mTorr, alternatively about 40 mTorr to about 50 mTorr, alternatively about 50 mTorr to about 60 mTorr, alternatively about 60 mTorr to about 80 mTorr, alternatively about 80 mTorr to about 100 mTorr.

In at least one embodiment, the microwave energy applied to the process gas during operation 306 is about 25 W to about 300 W, such as about 50 W to about 250 W, such as about 100 W to about 200 W, alternatively about 25 W to about 50 W, alternatively about 50 W to about 100 W, alternatively about 100 W to about 150 W, alternatively about 150 W to about 200 W, alternatively about 200 W to about 250 W, alternatively about 250 W to about 300 W, alternatively about 50 W to about 150 W. In some embodiments, the microwave energy is provided at frequencies in the “S-band”, such as frequencies between about 2.4 GHz and about 2.6 GHz, such as about 2.45 GHz. The microwave energy may be applied to the process gas for about 1 min to about 10 min, such as about 2 min to about 8 min, such as about 4 min to about 6 min, alternatively about 1 min to about 2 min, alternatively about 2 min to about 4 min, alternatively about 4 min to about 5 min, alternatively about 5 min to about 6 min, alternatively about 6 min to about 8 min, alternatively about 8 min to about 10 min, alternatively about 2 min to about 5 min.

For example, the microwave oxidation etch process occurs in a processing chamber held at a temperature of about 100° C. to about 350° C. and a pressure of about 1 mT to about 15 mT, such as 7.5 mT, while the microwave energy at about 100 W to about 150 W, such as 125 W, is applied to the process gas (e.g., O₂) flowed into the processing chamber at about 1 sccm to about 15 sccm, such as 10 sccm, for about 10 seconds to about 400 seconds, such as 180 seconds to about 300 seconds. In one or more embodiments, the processing time (e.g., about 10 seconds to about 400 seconds) includes the length of time the O₂ gas is flowed into the chamber and/or the length of time the microwave energy is applied to the O₂ gas. In one or more embodiments, the etch process of operation 306 occurs in one processing chamber (e.g., processing chambers 120, 122, 124, 126, 128, 130, or 132 as shown in FIG. 1). In one or more embodiments, when the microwave oxidation etch process occurs at a lower temperature, the time of the microwave oxidation etch process increases. For example, when the microwave oxidation etch process occurs at a lower temperature such as 50° C., the microwave oxidation etch process includes a longer time for etching such as five sequential rounds of 300 seconds each round. In one or more embodiments, when a higher temperature is used during the microwave oxidation etch process, a shorter time for etching is used.

At operation 308, as shown in FIG. 4D, a metal gap fill material 428 is deposited in a bottom-up growth process at least partially into the cavity 410. In one or more embodiments, the bottom-up growth process used to deposit the metal gap fill material 428 conformally deposits the metal gap fill material 428 in the cavity 410 over at least one layer (e.g., the first layer 406 or the second layer 408), the silicon-based portion 404, and the bottom surface 426.

The metal gap fill material 428 may be formed by any suitable deposition process such as an atomic layer deposition (ALD) process, a chemical vapor deposition (CVD) process, a hybrid ALD/CVD process, a plasma enhanced ALD (PEALD) process, a plasma enhanced CVD (PECVD) process, or the like. Any suitable deposition process, including but not limited to CVD or ALD processes, may be utilized for the bottom-up growth process. The metal gap fill material 428 may be applied such that the material is deposited onto the bottom portion of the device feature and then grown upwards towards the top-side surface 422 of the contact structure 400 such that the resultant gap fill material 428 at least approaches the top-side surface 422 (as shown in FIG. 3D) or is at least partially level with the top-side surface 422 (not shown).

In one or more embodiments, the metal gap fill material 428 includes one or more of cobalt (Co), molybdenum (Mo), tungsten (W), tantalum (Ta), titanium (Ti), ruthenium (Ru), rhodium (Rh), copper (Cu), iron (Fe), manganese (Mn), vanadium (V), niobium (Nb), hafnium (Hf), zirconium (Zr), yttrium (Y), aluminum (Al), tin (Sn), chromium (Cr), lanthanum (La), iridium (Ir), or any combination thereof. In one or more embodiments, the metal gap fill material 428 includes tungsten (e.g., deposited using WF6). In one or more embodiments, the metal gap fill material 428 includes molybdenum. For example, a conventional CVD approach using a processing chamber (e.g., processing chambers 120, 122, 124, 126, 128, 130, or 132 shown in FIG. 1) includes a processing chamber temperature of about 400° C., the processing gases (e.g., MoCl₅ and H₂) to be flowed into the chamber at about 500 sccm to about 12000 sccm, the processing chamber includes a pressure of about 50 Torr, and the process occurs for about 60 minutes. The metal gap fill material 428 is deposited such that the metal gap fill material 428 contacts at least the first layer 406 or the second layer 408 and the first sidewall 424a and the second sidewall 424b. After the metal gap fill material 428 is formed, the contact structure 400 may be planarized, by used of a chemical mechanical planarization process.

Embodiments of the present disclosure generally relate to non-plasma methods of processing a substrate. More specifically, the methods disclosed herein incorporate microwave oxidation that is used to selectively etch materials during semiconductor device manufacturing. Deposition of a metal gap fill material over a liner layer (e.g., the first layer or the second layer) may lead to seams forming within the feature, which causes increased resistivity. Conventional process used to etch liner layers (e.g., the first layer and the second layer disclosed above) cause damage to the dielectric material of the substrate, involve multiple steps, include long processing times, and require multiple processing chambers to form a contact structure. As disclosed within, a selective etching process that utilizes microwave enhanced non-plasma processing methods is used to selectively etch the liner layers at a low temperature, causing minimal damage to the dielectric material, involving one step, and requiring one processing chamber to perform the etch process. This allows for increased selectivity during the metal gap fill material deposition, prevents seam formation in the metal gap fill material, allows for a higher throughput of the process, lowers the cost of integration, and allows for a low resistivity of the resulting contact structure. Further, the methods disclosed herein are applicable in any BEOL or MOL process where an etch process is required. Overall, the use of microwave enhanced non-plasma processing methods provides an alternative to wet etching and conventional dry etching methods that is beneficial in semiconductor manufacturing.

While the foregoing is directed to embodiments of the present disclosure, other and further embodiments of the disclosure may be devised without departing from the basic scope thereof, and the scope thereof is determined by the claims that follow.

What is claimed is:

1. A method of etching a contact structure on a semiconductor substrate, the method comprising:
performing a microwave oxidation etch process on the contact structure by flowing a first process gas comprising oxygen over the contact structure and delivering a microwave energy to the first process gas without generating a plasma in a processing chamber, wherein:
the contact structure comprises a feature formed in a surface of the semiconductor substrate,
the feature is defined by a silicon-based portion, a bottom surface, a top-side surface, a first sidewall, and a second sidewall, and
at least one liner layer is disposed over the feature.

2. The method of claim 1, wherein the at least one liner layer comprises a first liner layer over the silicon-based portion, the bottom surface, the top-side surface, the first sidewall and the second sidewall.

3. The method of claim 2, wherein the first liner layer comprises titanium silicide.

4. The method of claim 2, wherein the at least one liner layer further comprises a second liner layer over the first liner layer, and wherein the second liner layer comprises titanium nitride, titanium silicon nitride, or combinations thereof.

5. The method of claim 1, wherein the first process gas is O₂.

6. The method of claim 1, wherein the microwave oxidation etch process selectively etches away the at least one liner layer such that the at least one liner layer is disposed over at least the silicon-based portion.

7. The method of claim 1, wherein, during the microwave oxidation etch process:
the process chamber is maintained at a temperature of about 100° C. to about 350° C. and a pressure of about 1 mT to about 15 mT,
the microwave energy applied to the first process gas is at about 100 W to about 150 W,
the first process gas is flowed into the processing chamber at about 1 sccm to about 15 sccm, and
the first process gas is flowed into the processing chamber for about 10 seconds to about 400 seconds.

8. A method of forming a contact structure on a semiconductor substrate, the method comprising:
performing a microwave oxidation etch process on the contact structure, wherein the microwave oxidation etch process comprises flowing a first process gas over the contact structure and delivering a microwave energy to the first process gas without generating a plasma in a processing chamber, wherein:
the contact structure comprises a feature formed in a surface of the semiconductor substrate,
the feature is defined by a silicon-based portion, a bottom surface, a top-side surface, a first sidewall, and a second sidewall,
a first liner layer is disposed over at least a portion of the feature, and
a second liner layer is disposed over at least a portion of the first liner layer; and
depositing a metal gap fill material over the contact structure to fill the feature.

9. The method of claim 8, wherein the first process gas is O₂.

10. The method of claim 8, wherein the microwave oxidation etch process selectively etches away the at least a portion of the first liner layer and at least a portion of the second liner layer such that the first liner layer and the second liner layer are disposed over the silicon-based portion and the bottom surface of the feature.

11. The method of claim 8, wherein, during the microwave oxidation etch process:
the process chamber is maintained at a temperature of about 100° C. to about 350° C. and a pressure of about 1 mT to about 15,
the microwave energy applied to the first process gas is at about 100 W to about

150 W,
the first process gas is flowed into the processing chamber at about 1 sccm to about 15 sccm, and
the first process gas is flowed into the processing chamber for about 10 seconds to about 400 seconds.

12. The method of claim 8, wherein the first liner layer comprises titanium silicide.

13. The method of claim 8, wherein the second liner layer comprises titanium nitride, titanium silicon nitride, or combinations thereof.

14. The method of claim 8, wherein depositing the first liner layer comprises:
maintaining a first temperature of a substrate is about 200° C. to 800° C.; and
providing a first carrier gas, a first metal-containing precursor, and a first hydrogen-containing precursor into a deposition chamber, wherein the first metal-containing precursor is TiCl₄, and wherein the first hydrogen-containing precursor is H₂.

15. The method of claim 8, wherein depositing the second liner layer comprises:
maintaining a first temperature of a substrate is about 200° C. to 800° C.; and
providing a second carrier gas, a second metal-containing precursor, a nitrogen-containing precursor, and a second hydrogen-containing precursor into a deposition chamber, wherein the second metal-containing precursor is TiCl₄, wherein the nitrogen-containing precursor is N₂, and wherein the second hydrogen-containing precursor is H₂.

16. The method of claim 8, wherein the metal gap fill material comprises cobalt (Co), molybdenum (Mo), tungsten (W), tantalum (Ta), titanium (Ti), ruthenium (Ru), rhodium (Rh), copper (Cu), iron (Fe), manganese (Mn), vanadium (V), niobium (Nb), hafnium (Hf), zirconium (Zr), yttrium (Y), aluminum (Al), tin (Sn), chromium (Cr), lanthanum (La), iridium (Ir), or any combination thereof.

17. A method of forming a contact structure on a semiconductor substrate, the method comprising:
forming a first liner layer over the contact structure by maintaining a first temperature of the semiconductor substrate and providing a first carrier gas, a first metal-containing precursor, and a first hydrogen-containing precursor to a first processing chamber, wherein:
the contact structure comprises a feature formed in a surface of the semiconductor substrate,
the feature is defined by a silicon-based portion, a bottom surface, a top-side surface, a first sidewall, and a second sidewall, and
the first liner layer is disposed over at least a portion of the feature; and
performing a microwave oxidation etch process on the contact structure, wherein the microwave oxidation etch process comprises flowing a first process gas over the contact structure and delivering a microwave energy to the first process gas without generating a plasma in a processing chamber.

18. The method of claim 17, wherein the microwave oxidation etch process selectively etches away the at least a portion of the first liner layer such that the first liner layer is disposed over the silicon-based portion and the bottom surface of the feature.

19. The method of claim 17, wherein, during the microwave oxidation etch process:
the process chamber is maintained at a temperature of about 100° C. to about 350° C. and a pressure of about 1 mT to about 15 mT,
the microwave energy applied to the first process gas is at about 100 W to about 150 W,
the first process gas is flowed into the processing chamber at about 1 sccm to about 15 sccm, and
the first process gas is flowed into the processing chamber for about 10 seconds to about 400 seconds.

20. The method of claim 17 further comprising:
depositing a metal gap fill material over the contact structure to fill the feature, wherein the metal gap fill material contacts the first sidewall, the second sidewall, and at least a portion of the first liner layer.
